(19) United States
(12) Patent Application Publication
(10) Pub. No.: US 2008/0266981 A1
(43) Pub. Date: Oct. 30, 2008

(54) NONVOLATILE MEMORY DEVICES AND METHODS OF FORMING THE SAME

(76) Inventors: KWANG WOOK KOH, Seoul (KR); Jeong-Uk Han, Suwon-si (KR)

Correspondence Address: Frank Chau, Esq.;F. CHAU & ASSOCIATES, LLC, 130 Woodbury Road, Woodbury, NY, 11797, US

(21) Appl. No.: 12/173,742

(22) Filed: Jul. 15, 2008

Related U.S. Application Data
(62) Division of application No. 11/232,284, filed on Sep. 21, 2005.

(30) Foreign Application Priority Data
Sep. 21, 2004 (KR) 2004-75606

(51) Int. Cl. G11C 11/34; H01L 29/788

(52) U.S. Cl. 365/185.28; 257/319; 257/E29.3

(57) ABSTRACT

A nonvolatile memory device includes first and second impurity diffusion regions formed in a semiconductor substrate, and a memory cell formed on a channel region of a semiconductor substrate between the first and second impurity diffusion regions. The memory cell includes a stacked gate structure formed on the channel region, and first and second select gates formed on the channel regions and opposite sidewalls of the stacked gate structure. Since the first and second select gates are spacer-shaped to be self-aligned on opposite sidewalls of the stacked gate structure, a size of a memory cell is reduced to enhance an integration density of a semiconductor device.

This application is a divisional of U.S. patent application Ser. No. 11/232,284, filed on Sep. 21, 2005 which in turn claims priority under 35 U.S.C. § 119 to Korean Patent Application No. 10-2004-75606 filed on Sep. 21, 2004, the disclosures of which are each all incorporated herein by reference in their entirety.

### BACKGROUND OF THE INVENTION

1. Field of the Invention

The present invention relates to semiconductor devices and methods of forming the same. More specifically, the present invention is directed to nonvolatile memory devices and methods of forming the same.

2. Description of the Related Art

Memory can be split into two main categories: volatile and nonvolatile. Volatile memory loses any stored data as soon as the system is turned off. Electrically erasable programmable read-only memories (EEPROMs) are a kind of nonvolatile memory which keep stored data even when their power supplies are interrupted.

Generally, memory cell structures of nonvolatile memory devices may be classified into two categories, namely, a split gate structure and a stacked gate structure. A conventional stacked gate memory cell is illustrated in FIG. 1. As shown in FIG. 1, a floating gate 15 and a control gate 19 are sequentially stacked on a substrate 11. A tunneling oxide layer 13 is sandwiched between the substrate 11 and the floating gate 15, and a blocking oxide layer 17 is sandwiched between the floating gate 15 and the control gate 19. Source and drain junction areas 21S and 21D are disposed in a substrate outside of the stacked gate structure. In the stacked gate memory cell, channel hot carrier injection (CHEI) is used to perform a programming operation at the side of the drain region 21D, and Fowler-Nordheim tunneling (F-N tunneling) is used to perform an erasing operation at the side of the source region 21S. The smaller size of a stacked gate memory cell makes high integration possible. Thus, such stacked gate cells have been used widely.

It is known that stacked gate cells suffer from over-erase effects. The over-erase effects occur when a floating gate is excessively discharged during an erasing operation at a stacked gate memory cell. Since threshold voltages of the excessively discharged memory cell have a negative value, current flows even when the memory cell is not selected, i.e., when a read voltage is not applied to a control gate.

Two types of memory cells are made to eliminate over-erase effects. One type is the two-transistor memory cell, and the other is the split gate memory cell. FIG. 2 illustrates a conventional two-transistor memory cell, in which a select transistor 20 spaced apart from a conventional stacked gate memory cell 10 is additionally adopted. Program and erase are conducted at the stacked gate memory cell 10. When the memory cell 10 is not selected, a select gate 15s suppresses the leakage current caused by an excessively discharged floating gate 15 of the memory cell. However, in the case of such a two-transistor memory cell structure there is difficulty in achieving high integration of memory devices because there is an impurity diffusion region 21D between the stacked gate memory cell 10 and the select transistor 20.

FIG. 3 illustrates a conventional split gate memory cell 30, wherein a select gate 15s and a control gate 19 of the stacked gate memory cell of FIG. 2 are merged into one control gate 39. A portion of the control gate 39 is formed over a substrate 11. An insulating layer 33a is interposed without intervention of a floating gate 35. That is, there are two separate channels 43c1 and 43c2 below the stacked gate. When the control gate 39 is turned off, the select gate channel 43c1 disposed below the control gate 39 prevents a leakage current from the floating gate channel 43c2 disposed below an excessively discharged floating gate 35. However, the split gate memory cell is characterized by programming efficiency, and a relatively high drain voltage is required. In a split gate memory cell, it is necessary that the select gate channel 43c1 disposed below the control gate 39 be maintained at a constant length. This may result in a misalignment during formation of the control gate 39, with the trend toward smaller semiconductor device features.

### SUMMARY OF THE INVENTION

Exemplary embodiments of the present invention are directed to a nonvolatile memory device having a small-sized memory cell and a method of forming the same. In various exemplary embodiments of the present invention, the nonvolatile memory device performs program and erase operations using F-N tunneling and includes a stacked gate structure and first and second select gate electrodes.

According to an exemplary embodiment of the present invention, the stacked gate structure includes a floating gate electrode and a control gate electrode which are sequentially stacked on a semiconductor substrate. The first and second select gate electrodes are self-aligned on opposite sidewalls of the stacked gate structure. A first insulation layer is interposed between the stacked gate structure and the substrate. F-N tunneling occurs at the first insulation layer. A second insulation layer is interposed between the floating gate electrode and the control gate electrode. A third insulation layer is interposed between the select gate electrodes and the stacked gate structure and between the select gate electrodes and the substrate.

In the nonvolatile memory device, according to an exemplary embodiment of the present invention, the select gate electrodes are self-aligned on the opposite sidewalls of the stacked gate electrode to reduce a size of the nonvolatile memory device. Over-erase effects are avoided due to the select gate electrodes. A first impurity diffusion region and a second impurity diffusion region are disposed in a semiconductor substrate outside the first and second gate electrode, acting as a drain region and a source region. That is, the stacked gate structure and the select gates are disposed between the first and second impurity diffusion regions. As a result, a channel region is formed in a substrate below the stacked gate structure and the select gate electrodes.

A bit line is connected to one of the impurity diffusion regions (e.g., a first impurity diffusion region or a drain region). In an exemplary embodiment of the present invention, the first impurity diffusion region is disposed to be adjacent to the first select gate electrode, and the second impurity diffusion region (source region) is disposed to be adjacent to the second select gate electrode.

Preferably, the semiconductor substrate includes a plurality of P-type pocket wells spaced apart from each other in an N-type well. A plurality of memory cells are arranged in the respective P-type pocket wells. A control gate electrode extends in a row direction to form a wordline. First and second select gate electrodes extend along a row direction to form first and second select line, respectively. The second impurity diffusion region extends in a row direction to form a common source line. The first impurity diffusion regions (drain regions) of a column direction are electrically connected to a bitline.

In an exemplary embodiment of the present invention, first impurity diffusion regions of adjacent memory cells are adjacent to each other, and second impurity diffusion regions of adjacent memory cells are adjacent to each other. Adjacent first impurity diffusion regions may be formed in the same pocket well or different pocket wells. Similarly, adjacent second impurity diffusion regions may be formed in the same pocket well or different pocket wells.

In various exemplary embodiments of the present invention, each of the P-type pocket wells includes k*8n memory cells, where n and k are positive integers, k is the number of rows in arrangement of floating gate electrodes arranged in a matrix of rows and columns, and 8n is the number of columns in arrangement thereof. First and second impurity diffusion regions are disposed at opposite sides of the respective memory cells. Adjacent source regions (first impurity diffusion regions) disposed in a column direction may be formed in different pocket wells or the same pocket well. Adjacent drain regions may be formed similar to the source regions, as described above.

If the adjacent drain regions are formed in the same pocket well, each of the P-type pocket wells may include 2^{k}*8n memory cells, where n and k are positive integers, 2^{k} is the number of rows, and 8n is the number of columns. First and second impurity diffusion regions are disposed at opposite sides of the respective memory cells. That is, the number of wordlines crossing the P-type pocket well is 2^{k-1} and the number of bitlines crossing the P-type pocket well is 8n. The adjacent source regions (first impurity diffusion regions) disposed in the column direction may be formed in different pocket wells or the same pocket well.

In a memory cell array, according to an exemplary embodiment of the present invention, a program operation for a specific memory cell is conducted by applying a program voltage to a selected wordline connected to the selected memory cell and floating unselected wordlines except the selected wordline; applying an operation voltage to the first select line; applying a ground voltage to the second select line, applying a ground voltage to a selected bitline connected to the selected memory cell and applying an operation voltage to unselected bitlines except the selected bitline; and applying a ground voltage to the common source line and the pocket well. Thus, a strong electric field is induced to a channel region below the floating gate electrode of the selected memory cell, so that charges are accumulated to the floating gate by F-N tunneling through the first insulation layer of the specific memory cell.

On the other hand, an electric field below the floating gate of unselected memory cells except the selected memory cell is affected by an operation voltage based on the unselected bitline. Therefore, a program for the unselected memory cells is not conducted.

An erase operation according to various exemplary embodiments of the present invention may be conducted for byte-data or sector-data; that is, the erase operation may be conducted for byte- or sector-memory cells formed in a pocket well. A ground voltage 0V is applied to a selected wordline connected to byte- or sector-memory cells to be erased (selected memory cells), and unselected wordlines are floated except the selected wordline. An erase voltage Vee is applied to a pocket well including the selected memory cells, and a ground voltage is applied to the other pocket wells. In addition, the first select line, the second select line, the common source line, and the bitline are floated. Thus, charges stored in floating gate electrodes of unselected memory cells are emitted to a pocket well through the first insulation layer due to F-N tunneling.

For example, if a P-type pocket well includes 1*8 memory cells (8 memory cells disposed in a row direction), a 1-byte erase operation may be conducted. It is assumed that a P-type pocket well includes 2*8 memory cells (8 memory cells disposed in a row direction and 2 memory cells disposed in a column direction). Under this assumption, 2 memory cell columns of the P-type pocket well are controlled by different wordlines. Thus, if wordlines of the same pocket well are all grounded, 8 memory cells connected to a ground wordline are erased. That is, a 1-byte erase operation is conducted.

To perform a read operation for reading out information stored in a specific memory cell (selected memory cell), according to an exemplary embodiment of the present invention, a ground voltage 0V is applied to a common source line and a pocket well. A first read voltage Vread1 is applied to a selected bitline connected to the selected memory cell, and a ground voltage is applied to unselected bitlines except the selected bitline. A second read voltage Vread2 is applied to a selected wordline connected to the selected memory cell, and a blocking voltage Vblock is applied to unselected wordlines except the selected wordline. An operation voltage is applied to a first select line of the selected memory cell, and a ground voltage is applied to unselected first select line except the selected first select line. An operation voltage is applied to a second select line.

In another exemplary embodiment of the present invention, there is provided a nonvolatile memory device including memory cells arranged in a matrix of rows and columns and source/drain regions formed in a substrate disposed at opposite sides of the memory cells.

In various exemplary embodiments of the present invention, each of the memory cells includes a stacked gate structure formed on a semiconductor substrate with a first insulation layer interposed therebetween, a first select gate, and a second select gate. The stacked gate structure includes a floating gate, a second insulation layer, and a control gate which are stacked in this order. The first and second select gates are self-aligned on opposite sidewalls of the stacked gate structure. Control gates of the memory cells disposed in a row direction are connected to form a wordline, and first select gates disposed in a row direction are connected to form a first select line. Further, second select gates disposed in a row direction are connected to form a second select line.

Source regions of a pair of adjacent memory cells disposed in a column direction are adjacent to each other, and drain regions of a pair of memory cells disposed in a column direction are adjacent to each other. Source regions disposed in a row direction are connected to form a common source line. Drain regions disposed in a column direction are electrically connected to a bitline.

In another exemplary embodiment of the present invention, there is provided a method of forming a nonvolatile memory device. The method includes preparing a semiconductor substrate of a first conductivity type; forming a stacked gate structure on the substrate of the first conductivity type with a first insulation layer interposed therebetween, the stacked gate structure including a charge storage layer, a second insulation layer, and a first gate electrode; forming a second gate electrode spacer and a third gate electrode spacer on opposite sidewalls of the stacked gate structure and the semiconductor substrate with a third insulation layer interposed therebetween to form a memory cell including the stacked gate structure and the second and third electrode spacers on the opposite sidewalls of the stacked gate structure; and forming a first impurity diffusion region adjacent to the second gate electrode spacer and a second impurity diffusion region adjacent to the third gate electrode spacer at a semiconductor substrate disposed at opposite sides of the memory cell.

In an exemplary method of forming a nonvolatile memory device, the first and second gate electrode spacers are self-aligned on opposite sidewalls of the stacked gate structure. Accordingly, the size of a memory cell is reduced to form a nonvolatile memory device of high density integration.

### BRIEF DESCRIPTION OF THE DRAWINGS

FIG. 1 illustrates a conventional stacked gate memory cell.

FIG. 2 illustrates a conventional two-transistor memory cell.

FIG. 3 illustrates a conventional split gate memory cell.

FIG. 4 and FIG. 5 are cross-sectional views of a unit nonvolatile memory cell according to a preferred embodiment of the present invention.

FIG. 6A is a top plan view of the unit memory cell illustrated in FIG. 4 and FIG. 5.

FIG. 6B illustrates an exemplary cell arrangement of the unit memory cell of FIG. 6A repeatedly arranged in a mirror symmetry.

FIG. 7A and FIG. 8A are cross-sectional views taken along a line I-I′ of FIG. 6B, illustrating memory cells according an exemplary embodiment of the present invention.

FIG. 7B and FIG. 8B are cross-sectional views taken along a line of II-II′ of FIG. 6B, illustrating memory cells according to an exemplary embodiment of the present invention.

FIG. 9 is an equivalent circuit diagram corresponding to the arrangement of FIG. 6B.

FIG. 10A through FIG. 16A and FIG. 10B through FIG. 16B are cross-sectional views, taken along lines I-I′ and II-II′ of FIG. 6B, for explaining a method of forming a nonvolatile memory cell according a preferred embodiment of the present invention.

FIG. 17A through FIG. 19A and FIG. 17B through FIG. 19B are cross-sectional views, taken along lines I-I′ and II-II′ of FIG. 6B, for explaining a method of forming a nonvolatile memory cell according a preferred embodiment of the present invention.

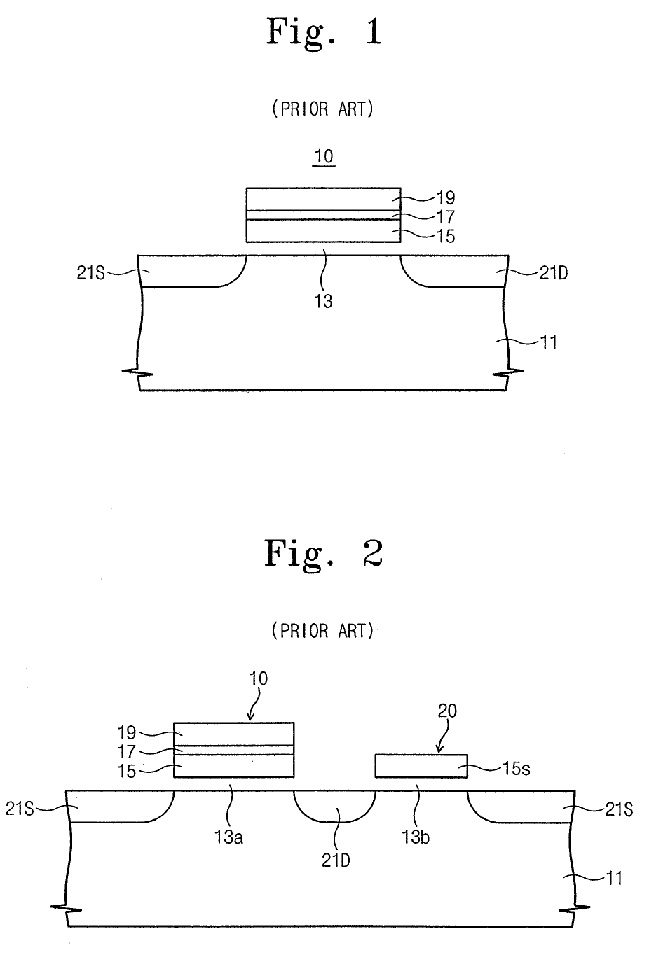

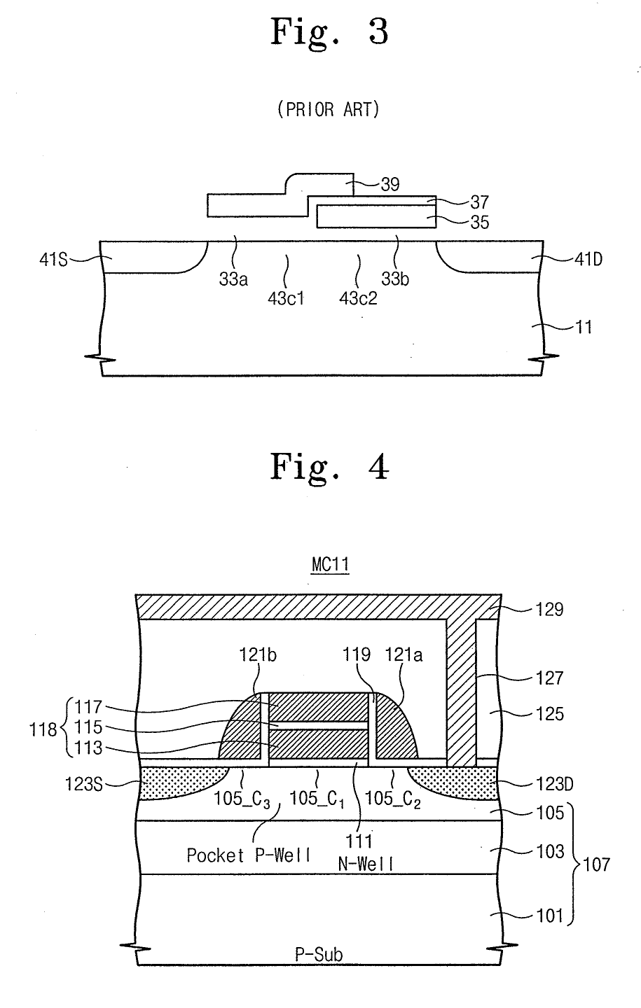

### DETAILED DESCRIPTION OF PREFERRED EMBODIMENTS

The present invention will now be described more fully hereinafter with reference to the accompanying drawings, in which preferred embodiments of the invention are shown. The invention may, however, be embodied in different forms and should not be construed as limited to the embodiments set forth herein. Rather, these embodiments are provided so that this disclosure will be thorough and complete, and will fully convey the scope of the invention to those skilled in the art. In the drawings, the height of layers and regions are exaggerated for clarity. It will also be understood that when a layer is referred to as being “on” another layer or substrate, it can be directly on the other layer or substrate, or intervening layers may also be present. Like numbers refer to like elements throughout the description of the figures.

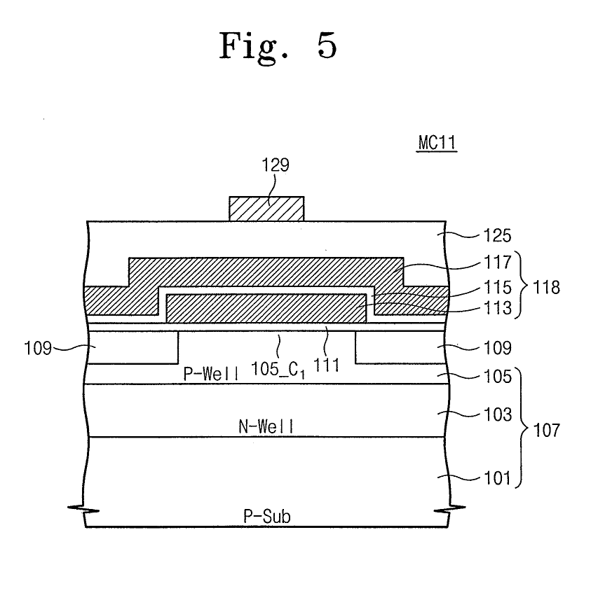

FIG. 4 and FIG. 5 are cross-sectional views of a unit nonvolatile memory cell according to an embodiment of the present invention. Specifically, FIG. 4 is a cross-sectional view taken along a bitline direction, and FIG. 5 is a cross-sectional view taken along a wordline direction.

As illustrated in FIG. 4 and FIG. 5, a nonvolatile memory cell MC11 includes a stacked gate structure 118 and first and second select gates 121a and 121b. The stacked gate structure 118 is formed on an active region 107 of a substrate with a first insulation layer 111 interposed therebetween. The first and second select gates 121a and 121b are spacer-shaped and self-aligned on opposite sidewalls of the stacked gate structure 118 with a third insulation layer 119 interposed therebetween. The stacked gate structure 118 includes a floating gate 113, a second insulation layer 115, and a control gate 117. Thus, the nonvolatile memory cell according to an exemplary embodiment of the present invention includes three gates, namely, the control gate 117, the first select gate 121a, and the second select gate 121b. As shown in FIG. 4, first and second impurity diffusion regions 123D and 123S are disposed in a substrate outside the first and second select gates 121a and 121b; that is, the stacked gate structure 118 and the first and second select gates 121a and 121b are disposed between the first and second impurity diffusion regions 123D and 123S. Accordingly, channel region 105_{—}c1 is formed in a substrate below the stacked gate structure 118, and channel regions 105_{—}c2 and 105_{—}c3 are formed in substrates below the first and second select gates 121a and 121b, respectively.

The first insulation layer 111 shown in FIGS. 4 and 5 is a tunneling insulation layer where tunneling (F-N tunneling) of charges occurs at program and erase operations. The first insulation layer 111 comprises, for example, thermal oxide and has a suitable thickness considering program and erase operation conditions. The second insulation layer 115 is an insulation layer interposed between the floating gate 113 and the control gate 117 and is a so-called blocking insulation layer to block a path of charges flowing therebetween. The second insulation layer 115 comprises, for example, oxide-nitride-oxide or oxide-nitride which are stacked in said order. The third insulation layer 119 electrically insulates the first and second select gates 121a and 121b from the stacked gate structure 118 and the active region 107 of the substrate. The third insulation layer 119 comprises, for example, oxide formed using chemical vapor deposition (CVD). It should be appreciated that any means for forming the oxide should be suitable for implementing the invention.

The active region 107 of the substrate includes an N-type well 103 formed at a bulk P-substrate 101 and a P-type well 105 formed in the N-type well 103. The N-type well 103 may include a plurality of P-type pocket wells 105, which will be described in detail later in this work.

Each P-type pocket well includes k*8n memory cells (n and k being positive integers, k being the number of rows, and 8n being the number of columns) and first and second impurity diffusion regions disposed at opposite sides of the respective memory cells. Preferably, memory cells of 2^{k-1} rows (k being a positive integer) and 8n columns (n being a positive integer) may be disposed at the respective P-type pocket wells 105. That is, 2^{k-1}*8n memory cells may be disposed at the respective P-type pocket wells (n and k being positive integers, 2^{k-1} being the number of memory cells arranged in a row direction, and 2n being the number of memory cells arranged in a column direction). Thus, byte erase or sector erase can be done if a suitable bias voltage is applied to the P-type pocket wells 105.

First and second impurity diffusion regions 123D and 123S are disposed in an active region 107 of a substrate at opposite sides of a memory cell MC11, i.e., in a P-type pocket well 105. The first impurity diffusion region 123D is disposed outside the first select gate 121a, and the second impurity diffusion region 123S is adjacent to the outside of the second select gate 121b. The impurity diffusion regions 123D and 123S may partially overlap the select gates 121a and 121b.

A bitline 129 is electrically connected to a first impurity diffusion region 123D outside the first select gate 121a.

Since the first and second select gates 121a and 121b of the memory cell MC11 are spacer-shaped and self-aligned on opposite sidewalls of the stacked gate structure 118, the memory cell MC11 has a small size to occupy a small area.

Program and erase of the memory cell MC11 is conducted through the first insulation layer 111 using F-N tunneling.

For the program operation, according to an exemplary embodiment of the present invention, a program voltage Vpp is applied to the control gate 117, an operation voltage Vcc is applied to the first select gate 121a, and a ground voltage 0V is applied to the drain region 123D, the second select gate 121b, and the source region 123S. Thus charges are injected into the floating gate 113 from the P-type pocket well 105, so that a memory cell has, for example, a first threshold voltage Vth1.

For the erase operation, according to an exemplary embodiment of the present invention, a ground voltage 0V is applied to the control gate 117, an erase voltage Vee is applied to the P-type pocket well 105, and the first select gate 121a, the second select gate 121b, the source region 123S, and the drain region 123D are floated. Thus, charges stored in the floating gate 113 are emitted to the P-type pocket well 105, so that a memory cell has, for example, a second threshold voltage Vth2.

For read operation, according to an exemplary embodiment of the present invention, a ground voltage 0V is applied to the source region 123S and the P-type pocket well 105, a first read voltage Vread1 is applied to the drain region 123D, a second read voltage Vread2 is applied to the control gate 117, and an operation voltage Vcc is applied to the first and second select gates 121a and 121b.

It should be understood that the first threshold voltage Vth1 of a programmed memory cell and the second threshold voltage Vth2 of an erased program cell may have various values. A second read voltage Vread2 applied to the control gate 117 may have a value between the first and second threshold voltages Vth1 and Vth2. For example, if a first threshold voltage of a programmed memory cell is 5V and a threshold voltage of an erased memory cell is 1V, a second read voltage Vread2 applied to the control gate 117 may have a value between 1V and 5V, e.g., approximately 3V. If the first threshold voltage is 2V and the second threshold voltage is −2V, the second read voltage Vread2 may have a value between −2V and 2V, e.g., approximately 0V.

For example, if the memory cell MC11 is programmed, a threshold voltage of the memory cell MC11, i.e., the stacked gate structure 118 has a first threshold voltage. Thus, a channel is not made under a read operation condition when a second read voltage Vread2 is applied to the control gate 117, a first read voltage Vread1 is applied to the drain region 123D, a ground voltage is applied to the source region 123S, and an operation voltage Vcc is applied to the first and second select gates 121a and 121b. On the other hand, if the memory cell MC11 is erased, the stacked gate structure 118 of the memory cell MC11 has a second threshold voltage. Thus, a channel is made between the source region 123S and the drain region 123D of the selected memory cell MC11 under the same read operation condition as described above. As a result, the memory cell MC11 can have different threshold voltages to store binary information.

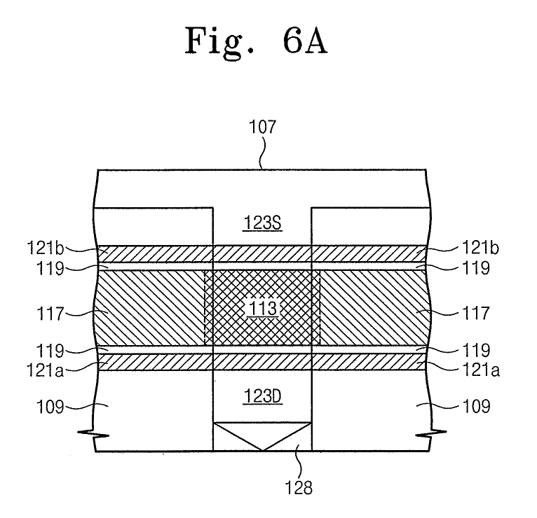

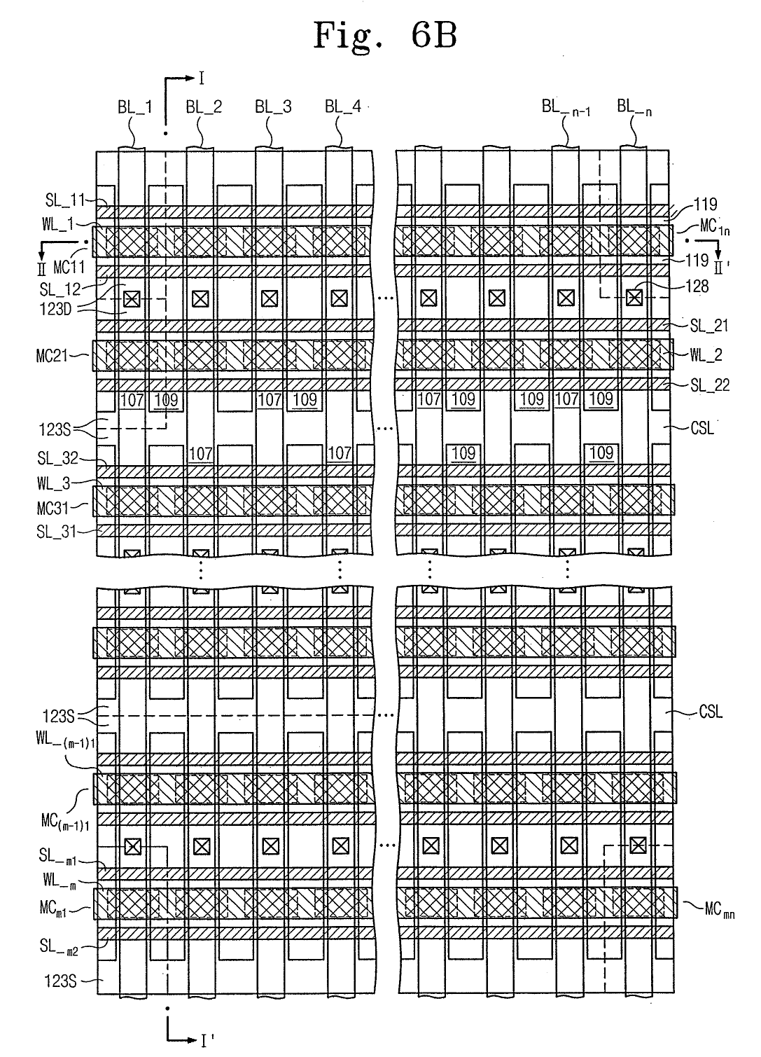

FIG. 6A is a top plan view of the unit memory cell MC11 illustrated in FIG. 4 and FIG. 5. FIG. 6B illustrates an exemplary cell arrangement of the unit memory cell of FIG. 6A repeatedly arranged in a mirror symmetry. As illustrated in FIG. 6B, memory cells MC11-MC1n, MC21-MC2n, . . . , and MCm1-MCmn are arranged in a row direction (x-axis or wordline direction) and a column direction (y-axis or bitline direction). Referring to FIG. 6A and FIG. 6B, active regions 107 are defined by device isolation regions 109. An active region portion extending in a horizontal direction (row direction) is to connect adjacent source regions 123S arranged in a row direction. A stacked gate structure is disposed at an active region portion extending in a vertical direction (column direction).

A plurality of wordlines WL_1-WL_m (control gate electrodes) are at right angles to active regions 107 extending in a vertical direction (y-axis direction), running in an x-axis direction (row direction). A plurality of bitlines BL_1-BL_n are at right angles to a wordline while running over the active regions 107 to be electrically connected to a drain region 123D through a bitline contact 128.

A second insulation layer 115, a floating gate 113, and a first insulation layer 111 are disposed between each wordline and a substrate. A floating gate 113, a second insulation layer 115, and a wordline (control gate) 117 constitute a stacked gate structure 118 (see FIG. 4 and FIG. 5). At opposite sides of each wordline, a first select line 121a and a second select line 121b are juxtaposed with a wordline 117. Referring to FIG. 6B, for example, a first select line SL_11 and a second select line SL_12 runs at opposite sides of a wordline WL_1. A first select line SL_11 and a second select line SL_12 correspond to a first select gate 121a and a second select gate 121b as illustrated in FIG. 4 and FIG. 5, respectively. Drain regions 123D are disposed in a substrate outside first select lines SL_11-SL_m1, and source regions 123S are disposed in a substrate outside second select lines SL_12-SL_m2.

Drain regions 123D arranged at the same column are electrically connected to the same bitline. Referring to FIG. 6B, in memory cells, two adjacent source regions 123S disposed in a column direction are electrically connected and adjacent source regions 123S disposed in a row direction are electrically connected to form a common source line CSL by an active region portion extending in a horizontal direction. Drain regions 123D of the same column are electrically connected to the same bitline.

Adjacent drain regions and source regions disposed in a column direction may be formed in the same P-type well or different pocket wells depending on how to form a P-type pocket well. That is, adjacent source regions disposed in a column direction may be formed at the same P-type pocket well or different pocket wells. However, in both cases, adjacent source regions disposed in a row direction are connected to form a common source line CSL. Similarly, adjacent drain regions disposed in a column direction may be formed in the same pocket well or different pocket wells. Preferably, adjacent drain regions disposed in a column direction are formed at the same P-type pocket well.

In an exemplary embodiment of the present invention, one P-type pocket well includes k*8n memory cells (n and k being positive integers, k being the number of rows, and 8n being the number of columns). Preferably, 8n memory cells (n being a positive integer) arranged in a row direction (wordline direction) and 2^{k-1} memory cells (k being a positive integer) arranged in a column direction may be disposed in one P-type pocket well. That is, one P-type pocket well may include 2^{k-1}*8n memory cells (n and k being positive integers, 2^{k-1} being the number of memory cells arranged in a column direction, and 8n being the number of memory cells arranged in a row direction).

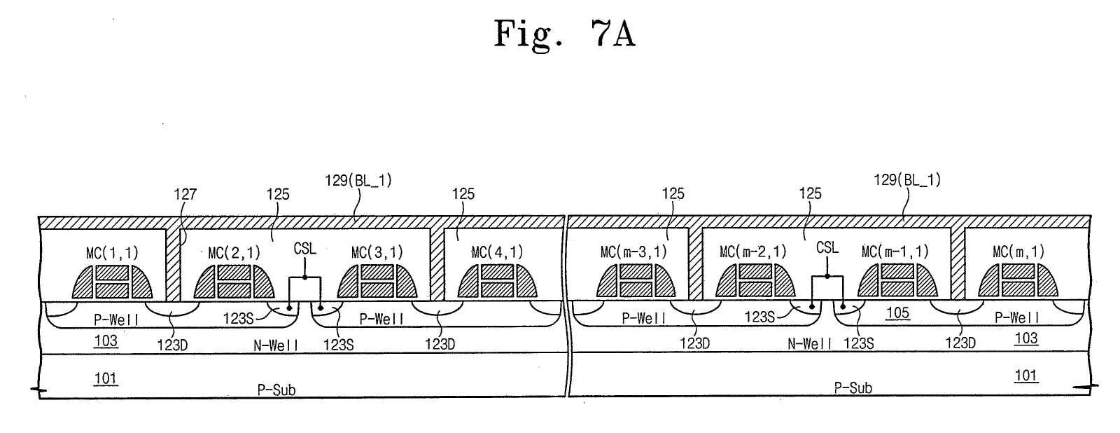

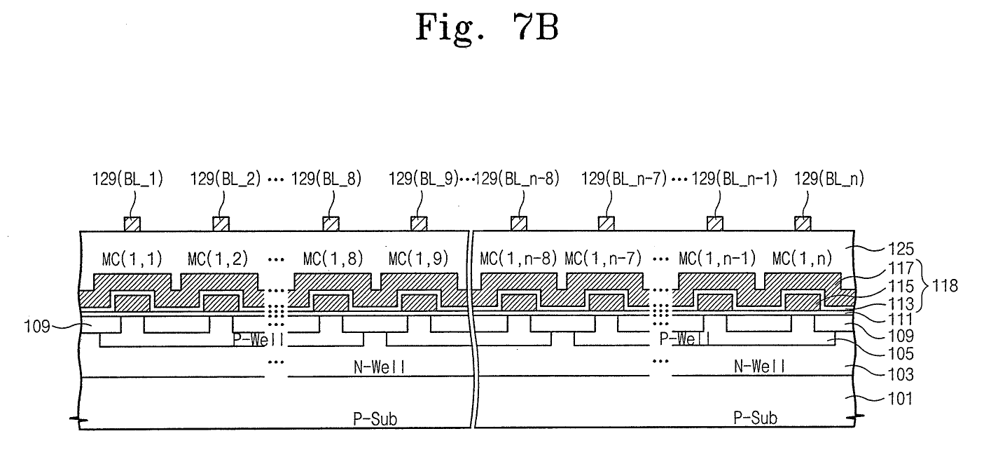

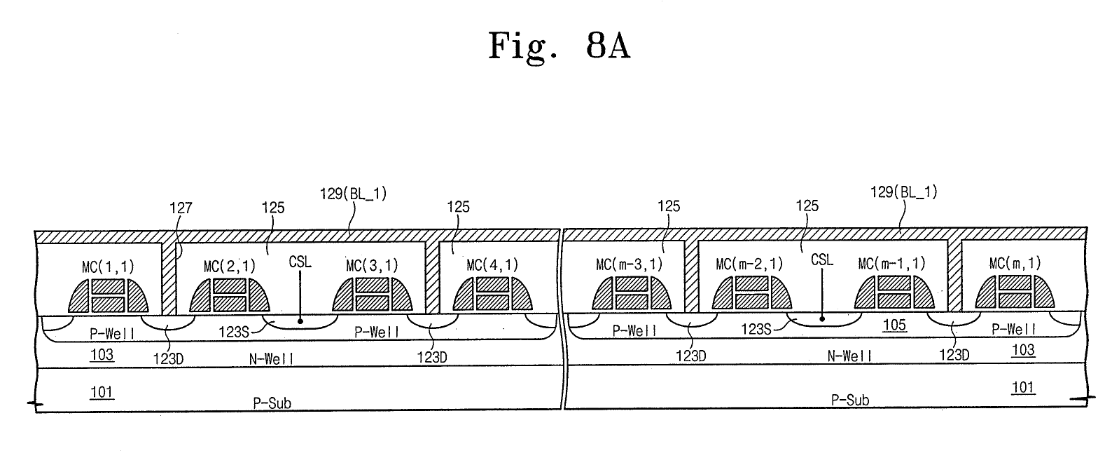

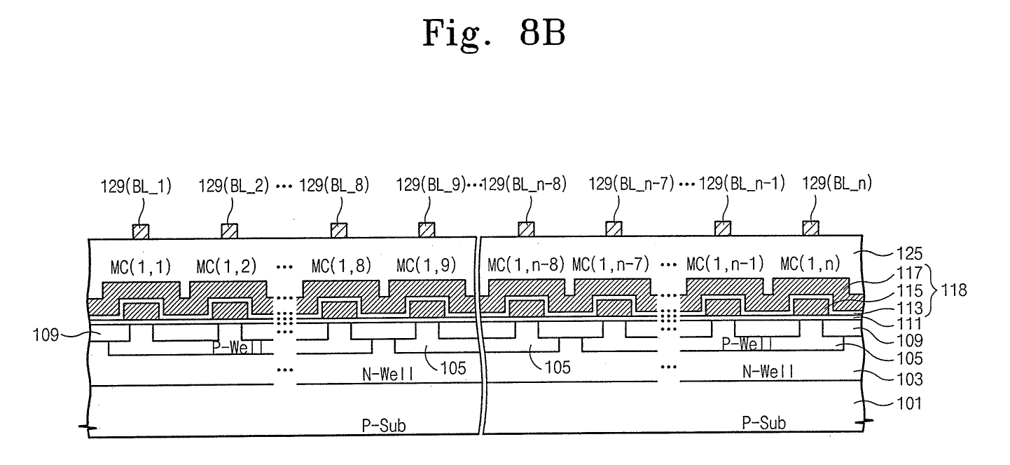

Hereinafter, an exemplary arrangement of memory cells in a P-type pocket well will be described with reference to FIG. 7A, FIG. 7B, FIG. 8A, and FIG. 8B.

FIG. 7A and FIG. 8A are cross-sectional views taken along a line I-I′ of FIG. 6B, illustrating memory cells according an exemplary embodiment of the present invention. FIG. 7B and FIG. 8B are cross-sectional views taken along a line of II-II′ of FIG. 6B, illustrating memory cells according to an exemplary embodiment of the present invention.

FIG. 7A and FIG. 7B illustrate an exemplary memory arrangement where 16 memory cells comprising 2 rows and 8 columns are formed in one P-type pocket well. FIG. 8A and FIG. 8B illustrate an exemplary memory arrangement wherein 32 memory cells comprising 4 rows and 8 columns are formed in one P-type pocket well.

Referring to FIG. 7A and FIG. 7B, 8 memory cells in a row direction and 2 memory cells in a column direction, e.g., memory cells MC11-MC18 and MC21-MC28, are formed in the same P-type pocket well. That is, two wordlines cross one P-type pocket well. In a memory cell, two adjacent source regions disposed in a column direction share an active region but are formed different P-type pocket wells. On the other hand, two adjacent drain regions disposed in a column direction are formed in the same P-type pocket well. In such an arrangement of memory cells, 1-byte data or 2-byte data may be erased in one erase operation. Although two adjacent source regions of a cell are formed in different pocket wells, it is preferable that they are electrically connected by a local interconnection.

Referring to FIG. 8A and FIG. 8B, 8 memory cells in a row direction and 4 memory cells in a column direction, i.e., memory cells MC11-MC18, MC21-MC28, MC31-MC38, and MC41-MC48, are formed in the same P-type pocket well. That is, four wordlines cross one P-type pocket well. In this case, a suitable bias voltage is applied to respective wordlines in the pocket well to erase 1-byte data, 2-byte data, 3-byte data or 4-byte data.

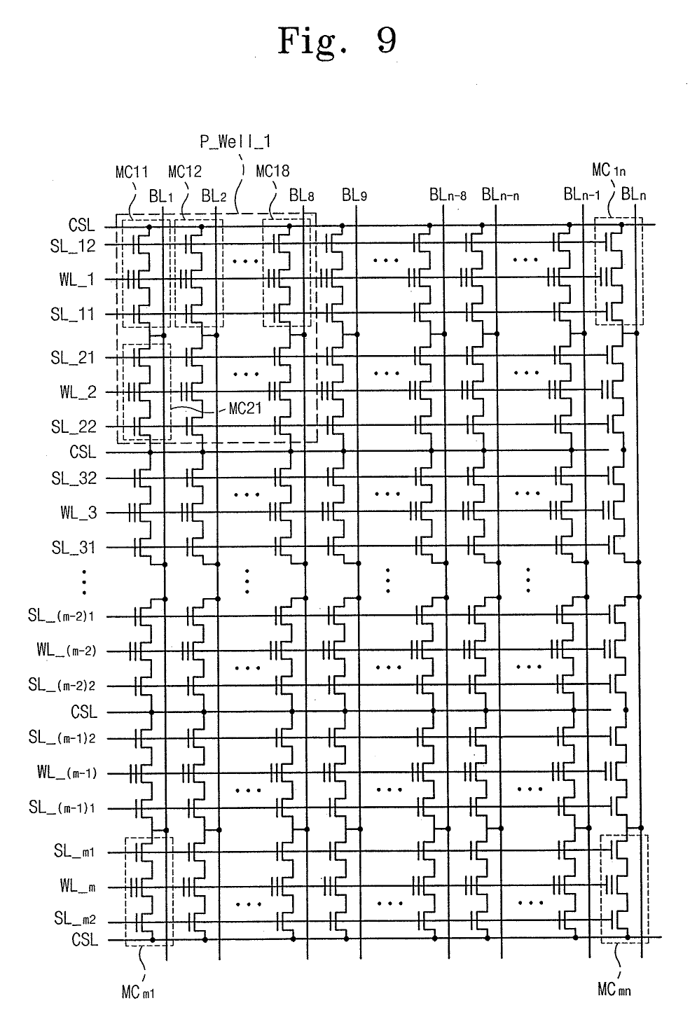

FIG. 9 is an equivalent circuit diagram of an exemplary memory cell array wherein memory cells of 2 rows and 8 columns (i.e., 16 memory cells) are formed in one P-type pocket well. Hereinafter, an operation condition for the memory cell arrangement will be described with reference to FIG. 9. As illustrated in FIG. 9, a plurality of wordlines WL_1-WL_m run in a row direction, and a plurality of bitlines runs in a column direction. At opposite sides of the respective wordlines, first select wordlines SL_11-SL_m1 and second select lines SL_12-SL_m2 run in parallel with the wordline. A bitline is electrically connected to a drain region outside the first select lines SL_11-SL_{—}m1. Source regions outside the second select lines SL_12-SL_m2 are connected to form a common source line CSL. A P-type pocket well has 16 memory cells of 2 rows and 8 columns. That is, two wordlines cross one pocket well, i.e., wordlines WL_1 and WL_2 cross a pocket well P-Well_1.

Hereinafter, program and read operations for a memory cell MC11 of one row and one column and a 1-byte erase operation for 8 memory cells in the pocket well P-Well_1, i.e., MC11-MC18, according to an exemplary embodiment of the present invention, will be described. The following table shows an operation condition for such an exemplary memory cell arrangement.

TABLE 1

| | | program | erase | Read |
|---|---|---|---|---|
| BL | selected BL | 0V | floating | Vread1 |
| | unselected BL | Vcc | | 0V |
| SL_1 | selected SL_1 | Vcc | floating | Vcc |
| | unselected SL_1 | 0V | | 0V |
| WL | selected WL | Vpp | 0V | Vread2 |
| | unselected WL | floating | floating | Vblock |
| SL_2 | selected SL_2 | 0V | floating | Vcc |
| | unselected SL_2 | | | |
| CSL | selected CSL | 0V | floating | 0V |
| | unselected CSL | | | |
| Pocket Well | selected pocket well | 0V | Vee | 0V |
| | unselected pocket well | | 0V | |

### (Program Operation)

In order to program a selected memory cell MC11, according to an exemplary embodiment of the present invention, a program voltage Vpp is applied to a wordline WL_1 (selected wordline) of a first row, and the other wordlines WL_2-WL_m (unselected wordlines) are floated; a ground voltage 0V is applied to a bitline BL_1 (selected bitline) of a first column, and an operation voltage Vcc is applied to the other bitlines BL_2-BL_n (unselected bitlines); an operation voltage Vcc is applied to a first select line SL_11 (selected first select line) of the first row, and a ground voltage 0V is applied to the other select lines SL_21, . . . , and SL_m1 (unselected first select lines); a ground voltage 0V is applied to a selected pocket well including a selected memory cell and unselected pocket wells except the selected pocket well; a ground voltage 0V is applied to a selected common source line CSL connected to a selected memory cell and unselected source lines CSL except the selected common source line; and a ground voltage 0V is applied to a selected second select line SL_12 of a selected memory cell and unselected second select lines SL_22, . . . , and SL_m2 except the selected second select line.

A program voltage can be, for example, about 15 to about 20 volts. An operation voltage Vcc has a value enough to create a channel below a first select gate, e.g., 3.5 volts approximately. It will be understood that the program and operation voltages may vary with different designs.

As previously stated, a program voltage Vpp, a ground voltage, and an operation voltage Vcc are applied to a selected wordline WL_1, a selected bitline BL_1, and a selected first select line SL_11, respectively. Thus, a strong electric field is induced below a floating gate of the selected memory cell MC11 to cause F-N tunneling. Due to the F-N tunneling, the selected memory cell MC11 connected to the selected wordline WL_1 is programmed. However, since an operation voltage Vcc is applied to unselected bitlines BL_2-BL_n and an operation voltage Vcc is applied to a selected first select line of a first row, an operation voltage Vcc is transmitted to unselected memory cells MC12-MC1n of the first row to weaken an electric field below a floating gate of the corresponding unselected memory cells MC12-MC1n. Thus, except for the selected memory cell MC11, the unselected memory cells MC12-MC1n of the first row are not programmed. Accordingly, a program disturbance, i.e., wordline disturbance by the selected wordline WL_1, does not occur.

Since the ground voltage is applied to the selected second select line SL_12, the selected memory cell MC1 is not affected by the other memory cells sharing the selected common source line CSL. Since the unselected wordlines WL_2-WL_m are floated, a strong electric field is not induced below the floating gate below the unselected memory cells MC21-MCm1 of the first row, although the selected bitline BL_1 is grounded and the ground voltage is applied to the unselected first select lines SL_21-SL_m1 (even if an operation voltage is applied to unselected first select lines). Further, since the unselected wordlines WL_2-WL_m are floated and an operation is applied to the unselected bitlines BL_2-BL_n, unselected memory cells MC22-MC2n, MC32-MC3n, and MCm2-MCmn are not programmed.

### (Erase Operation)

### <1-Byte Erase Operation>

According to an exemplary embodiment of the present invention, an erase voltage Vee is applied to a selected pocket well P-well_1, and a ground voltage is applied to unselected pocket wells except the selected pocket well. A ground voltage 0V is applied to a selected wordline WL_1 connected to selected memory cells MC11-MC18, and unselected wordlines WL_2-WL_m are floated. The other terminals, i.e., (selected and unselected) bitlines, (selected and unselected) first select lines, (selected and unselected) second select lines, and (selected and unselected) common source lines are floated. In an exemplary embodiment of the present invention, an erase voltage may have the same value as a program voltage.

Under the above-described operation condition, charged stored in 8 memory cells in a selected pocket well P-Well_1, i.e., 8 memory cells MC11-MC18 of a first row are emitted to perform a 1-byte erase operation. In order to prevent erasure of unselected memory cells MC 21-MC28 adjacent to the selected memory cells MC11-MC18 in the pocket well P-Well_1, unselected wordlines WL_2-WL_m are floated and unselected pocket wells are grounded (0V). Since the unselected wordline WL_2 connected to 8 memory cells MC21-MC28 of a second row formed in the same pocket well P-Well_1 is floated, an erase operation for these memory cells is not conducted. However, if a ground voltage is applied to a selected wordline WL_1 as well as an unselected wordline WL_2, a 2-byte erase operation may be conducted, as will be described below.

### <2-Byte Erase Operation>

According to an exemplary embodiment of the present invention, an erase voltage Vee is applied to a selected pocket well P-Well_1, and a ground voltage 0V is applied to selected bitlines WL_1 and WL_2. Common source lines CSL, first and second select lines, and bitlines are floated. Thus, charges stored in 16 memory cells in the selected pocket well P-Well_1, i.e., 8 memory cells MC11-MC18 of a first row and 8 memory cells of MC21-MC28 are emitted to perform a 2-byte erase operation. To prevent an erasure of unselected memory cells adjacent to the selected memory cells MC11-MC18 and MC21-MC28, unselected wordlines WL_3-WL_m are floated and an unselected pocket well is grounded (0V). As previously stated, an erase operation of various byte or sector data may be conducted depending on how to form a pocket well.

### (Read Operation)

Hereinafter, a read operation for a selected memory cell MC11 according to an exemplary embodiment of the present invention will be described. A first read voltage Vread1 is applied to a selected bitline BL_1 of a first row, and a ground voltage 0V is applied to unselected bitlines BL_2-BL_n. An operation voltage Vcc is applied to a first select line SL_11 of the first row, and a ground voltage 0V is applied to unselected first select lines SL_21-SL_m1. A second read voltage Vread2 is applied to a selected wordline WL_1, and a blocking voltage Vblock is applied to unselected wordlines WL_2-WL_m. The operation voltage Vcc is applied to the second select lines SL_21-SL_m2. A ground voltage 0V is applied to the other terminals, i.e., pocket wells and common source lines CSL.

The second read voltage Vread2 has an intermediate value, i.e., an average value between a threshold voltage Vth1 of a programmed memory cell and a threshold voltage Vth2 of an erased memory cell. The first read voltage Vread1 is applied to establish an electric field between a source and a drain at a read operation and may be approximately 1.8 volt. If the second read voltage Vread2 has a positive value, e.g., an operation voltage, the first read voltage Vread1 may have the same value as the second read voltage Vread1. The blocking voltage Vblock applied to the unselected wordlines WL_2-WL_m may have a magnitude sufficient to prevent formation of a channel below unselected memory cells. For example, if threshold voltages of the unselected memory cells all have positive values, the blocking voltage Vblock may be a ground voltage.

At a read operation, a ground voltage is applied to unselected first select lines SL_21-SL_m1 and a blocking voltage Vblock is applied to unselected wordlines WL_1-WL_{—}m. Thus, a read disturbance caused by unselected memory cells does not occur.

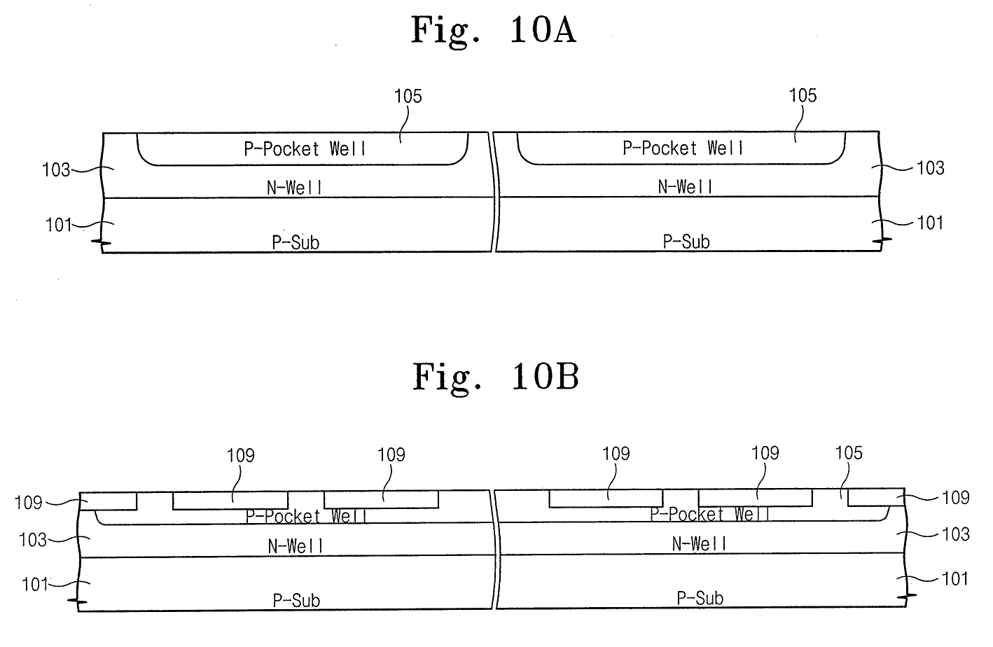

Hereinafter, a method of forming a nonvolatile memory device according to an exemplary embodiment of the present invention will be described with reference to FIG. 10A through FIG. 16A and FIG. 10B through FIG. 16B. In accordance with this exemplary embodiment, 16 memory cells are formed in one pocket well and a P-type semiconductor substrate is used.

FIG. 10A through FIG. 16A are cross-sectional views taken along a line I-I′ of FIG. 6B, and FIG. 10B through FIG. 16B are cross-sectional views taken along a line II-II′ of FIG. 6B. Referring to FIG. 10A and FIG. 10B, after forming an N-type well region 103 on a P-type semiconductor substrate 101, P-type pocket wells 105 are formed at the N-type well region 103. A device isolation layer 109 is formed using a device isolation process to define active regions. As illustrated in FIG. 10B, a P-type pocket well 105 and a device isolation region 109 are formed at respective pocket wells 105 such that 8 active regions are defined by the device isolation region 109 in a row direction. Formation of the device isolation region 109 is done using a conventional manner such as, but not limited to, a shallow trench isolation (STI).

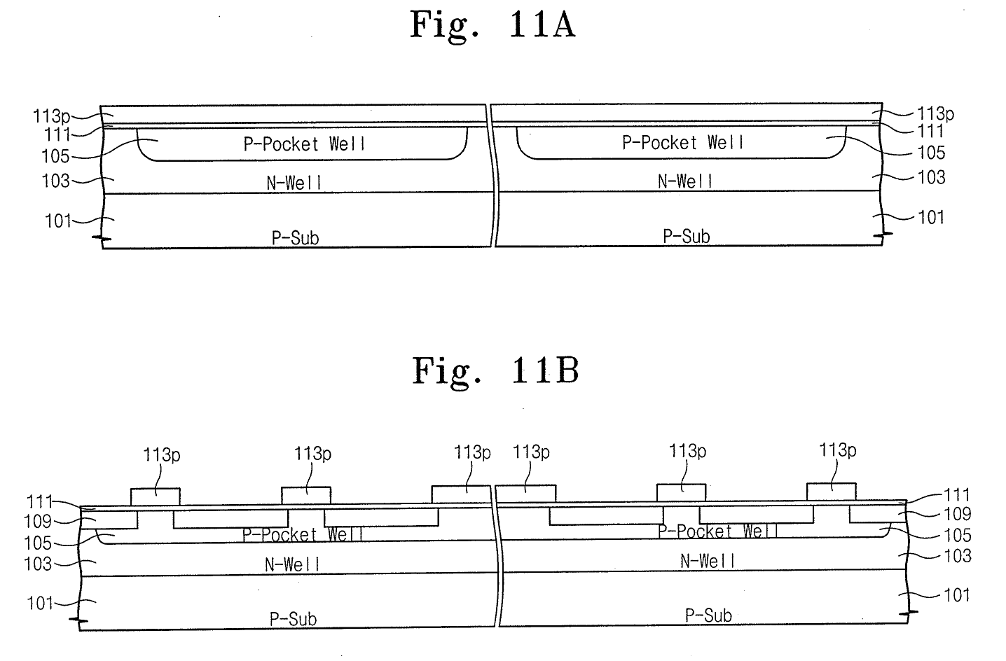

Referring to FIG. 11A and FIG. 11B, after forming a first insulation layer 111 where F-N tunneling occurs, a floating gate electrode pattern 113p is formed at an active region on the pocket well 105. The first insulation layer 111 comprises, for example, thermal oxide, and the floating electrode pattern 113p comprises silicon doped with impurities. It will be understood that any suitable material can be used for the first insulation layer 111 and floating electrode pattern 113p.

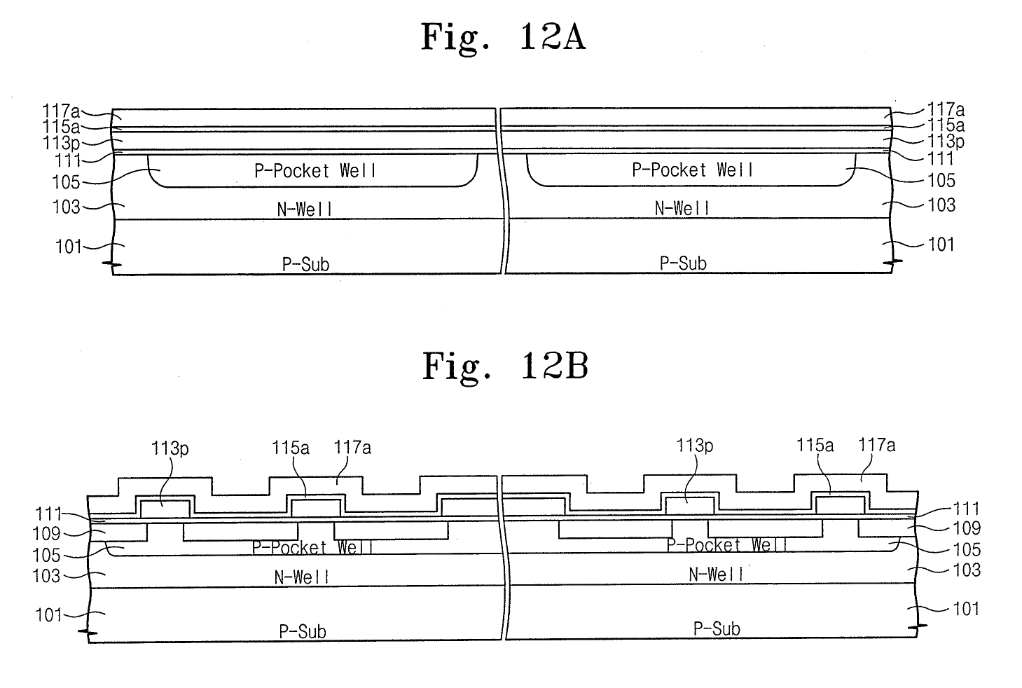

Referring to FIG. 12A and FIG. 12B, a second insulation layer 115a and a control gate electrode 117a are formed. The second insulation layer 115a may comprise, for example, oxide-nitride-oxide or oxide-nitride which are stacked in the order named. The control gate electrode 117a comprises, for example, silicon doped with impurities.

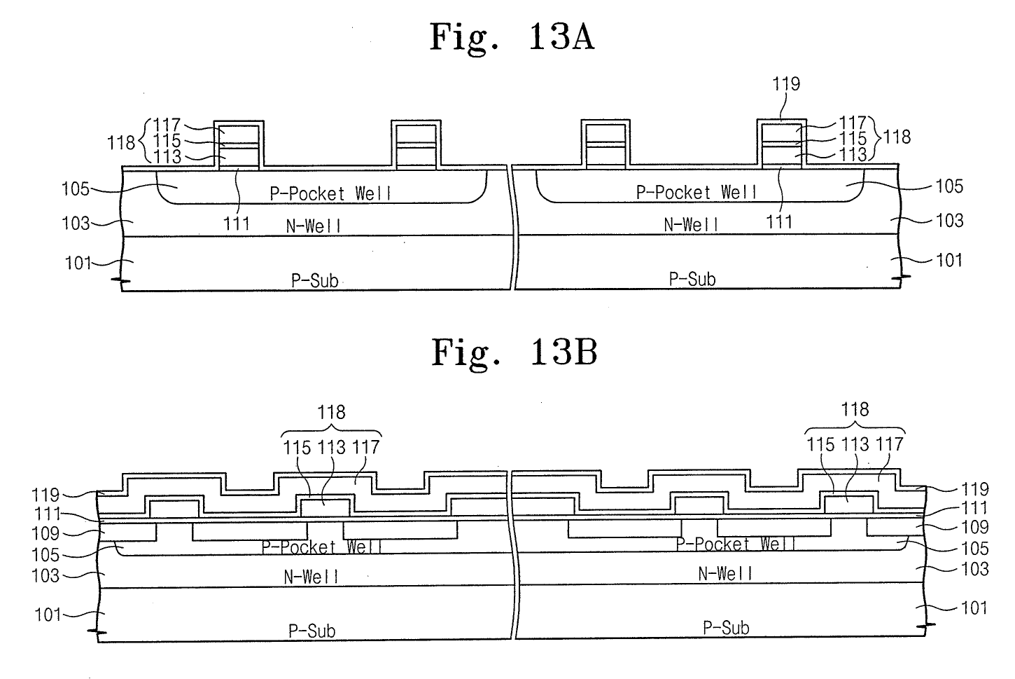

Referring to FIG. 13A and FIG. 13B, the stacked layers are patterned to form a stacked gate structure 118 including a first insulation layer 111, a floating gate electrode 113, a second insulation layer 115, and a control gate electrode 117. A third insulation layer 119 is formed on an entire surface of a substrate. Formation of the third insulation layer 119 may be done using, for example, chemical vapor deposition (CVD). It should be appreciated that any means for forming the third insulation layer 119 should be suitable for implementing the invention.

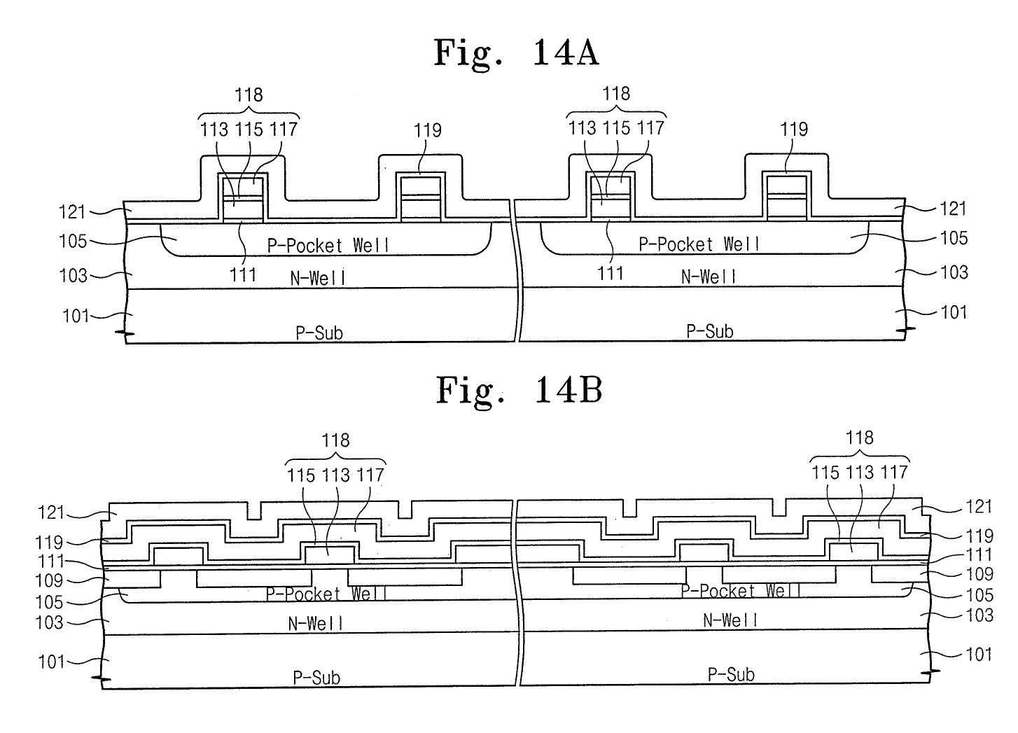

Referring to FIG. 14A and FIG. 14B, a conductive layer 121 is formed on a third insulation layer 119. The conductive layer 121 may comprise, for example, silicon doped with impurities. It will be understood that any suitable material can be used for the conductive layer 121.

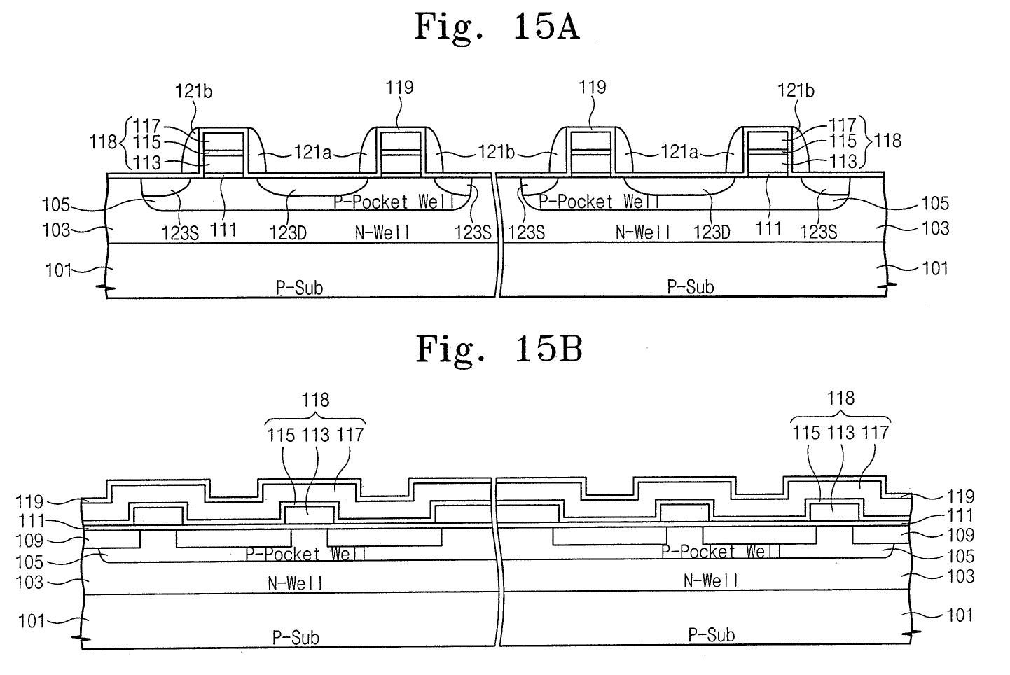

Referring to FIG. 15A and FIG. 15B, according to an exemplary embodiment of the present invention, the conductive layer 121 is etched back to form a first select gate (first select line) 121a and a second select gate (second select line) 121b which are self-aligned on opposite sidewalls of respective stacked gate structures 118. Thereafter, an ion implanting process is carried out to form a source region 123S and a drain region 123D at a P-type pocket well 105 disposed at opposite sides adjacent to the first and second select gates 121a and 121b.

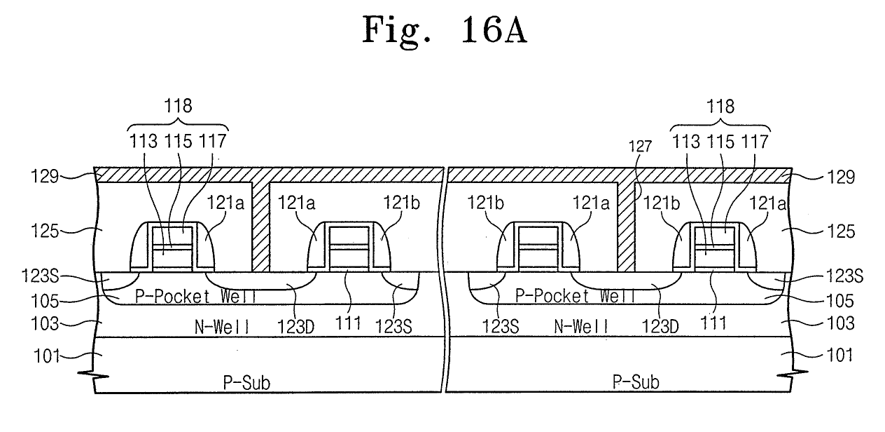

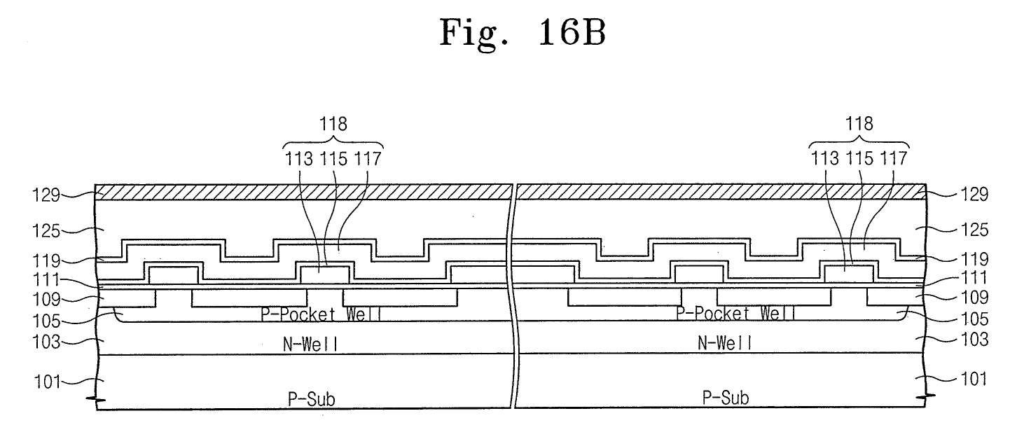

Referring to FIG. 16A and FIG. 16B, an interlayer dielectric 125 is formed. The interlayer dielectric 125 is patterned to form a contact hole 127 exposing a drain region 123D. A conductive material is deposited onto the interlayer dielectric 125 to fill a contact hole 127. A patterning process is then carried out to form bitlines 129 which are electrically connected to the drain region 123D.

According to the above-described exemplary method, first and second select gates are self-aligned on opposite sidewalls of a stacked gate structure to reduce a size of a memory cell.

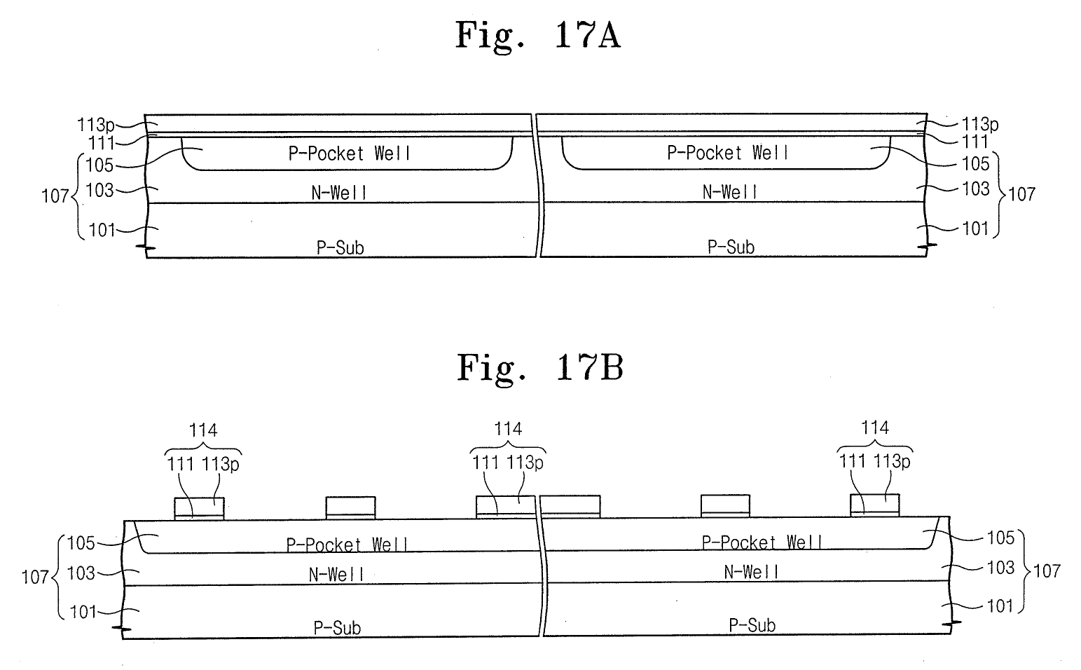

The floating gate pattern 113p may be self-aligned according to the self-alignment manner, i.e., at a device isolation process, according to various exemplary embodiments of the present invention, hereinafter described with reference to FIG. 17A through FIG. 19A and FIG. 17B through FIG. 19B. Referring to FIG. 17A and FIG. 17B, after forming an N-type well 103 and a P-type pocket well 105, a first insulation layer and a floating gate electrode layer are formed on a substrate 107. A patterning process is then carried out to form a trench etch mask 114 including a first insulation pattern 111 defining active regions and a floating gate electrode pattern 113p.

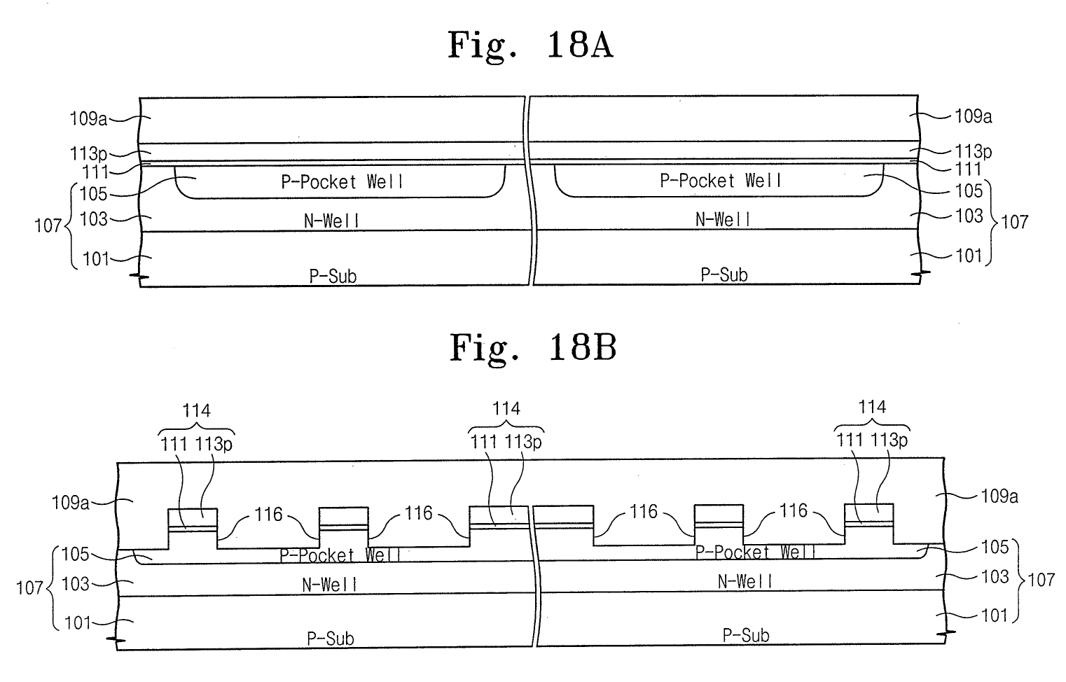

Referring to FIG. 18A and FIG. 18B, using the trench etch mask 114, an exposed substrate is etched to form a trench 116. An insulating material 109a is formed on the floating gate electrode pattern 113p to fill the trench 116.

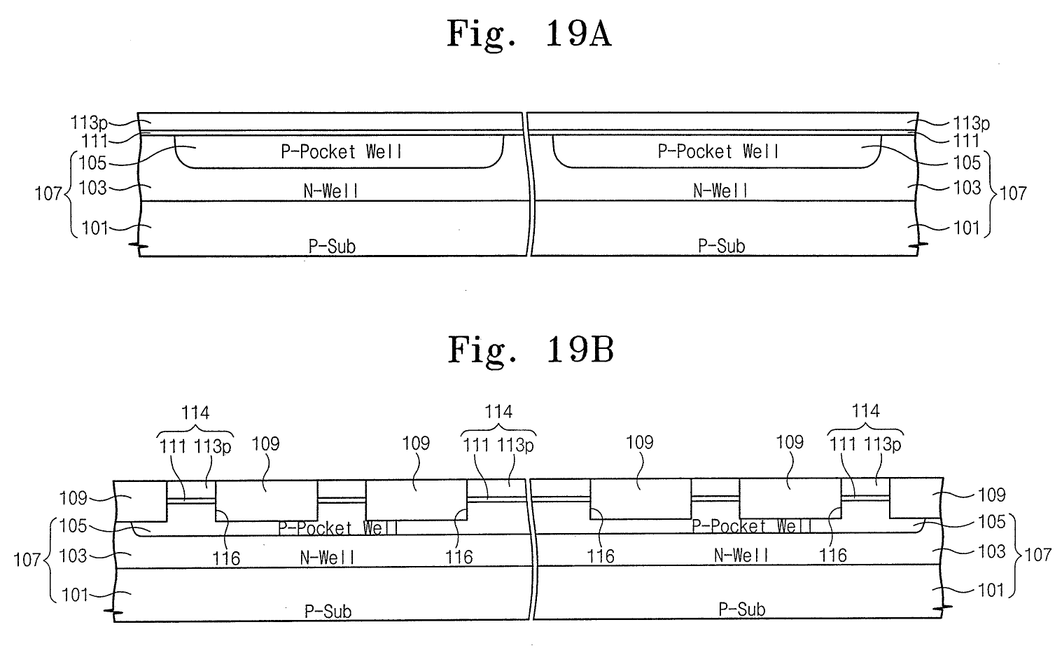

Referring to FIG. 19A and FIG. 19B, the insulating material 109a is planarized down to a top surface of the trench etch mask 114 to form a device isolation region 109. Thus, according to an exemplary embodiment of the present invention, a floating gate electrode pattern 113p is self-aligned between device isolation regions 109 simultaneously to formation of the device isolation region 109. The subsequent processes are performed in the same manner as previously described above.

Therefore, according to various exemplary embodiments of the present invention, a select gate is self-aligned on opposite sidewalls of a stacked gate structure. Thus, a select gate is formed without an additional photolithographic process and the size of a memory cell is reduced.

Although the processes and apparatus of the present invention have been described in detail with reference to the accompanying drawings for the purpose of illustration, it is to be understood that the inventive processes and apparatus are not to be construed as limited thereby. It will be readily apparent to those of reasonable skill in the art that various modifications to the foregoing exemplary embodiments may be made without departing from the spirit and scope of the invention as defined by the appended claims.

What is claimed is:

1. A nonvolatile memory device comprising:
a first impurity diffusion region and a second impurity diffusion region of a second conductivity type formed in a semiconductor substrate of a first conductivity type; and
a memory cell formed on a channel region of the semiconductor substrate between the first and second impurity diffusion regions, wherein the memory cell comprises:
a stacked gate structure including a floating gate, a second insulation layer, and a first gate electrode which are formed on the channel with a first insulation layer interposed therebetween; and
a second gate electrode spacer disposed adjacent to the first impurity diffusion region and a third gate electrode spacer disposed adjacent to the second impurity diffusion region, the second and third gate electrode spacers formed on opposite sidewalls of the stacked gate structure and the channel region with a third insulation layer interposed therebetween.

2. The nonvolatile memory device as recited in claim 1, wherein the floating gate, the first gate electrode, the second gate electrode spacer, and the third gate electrode spacer comprise doped silicon.

3. The nonvolatile memory device as recited in claim 1, wherein the first insulation layer comprises thermal oxide, the second insulation layer comprises oxide-nitride-oxide or nitride-oxide, and the third insulation layer comprises chemical vapor deposition (CVD) oxide.

4. The nonvolatile memory device as recited in claim 1, wherein the first and second impurity diffusion regions are self-aligned to a semiconductor substrate outside of the memory cell.

5. The nonvolatile memory device as recited in claim 1, wherein different bias voltages are independently applied to the second and third gate electrode spacers.

6. The nonvolatile memory device as recited in claim 1, wherein a program operation for the memory cell is conducted using F-N tunneling.

7. The nonvolatile memory device as recited in claim 6, wherein the program operation for the memory cell is conducted by applying a program voltage to the first gate electrode; applying an operation voltage to the second gate electrode spacer; and applying a ground voltage to the first impurity diffusion region, the third gate electrode spacer, the second impurity diffusion region, and the semiconductor substrate.

8. The nonvolatile memory device as recited in claim 1, wherein an erase operation for the memory cell is conducted by applying a ground voltage to the first gate electrode; applying an erase operation to the semiconductor substrate; and floating the second gate electrode spacer, the third gate electrode spacer, and the first and second impurity diffusion regions.

9. The nonvolatile memory device as recited in claim 1, wherein a read operation for the memory cell is conducted by applying a ground voltage to the second impurity diffusion region and the semiconductor substrate; applying a first read voltage to the first impurity diffusion region; applying a second read voltage to the first gate electrode; and applying an operation voltage to the second gate electrode spacer and the third gate electrode spacer.

10. The nonvolatile memory device as recited in claim 1, further comprising a well of the second conductivity type and a pocket well of the first conductivity type, the well being formed in the semiconductor substrate and the pocket well being in the well.

11. The nonvolatile memory device as recited in claim 10, wherein the well of the second conductivity type includes a plurality of the pocket well of the first conductivity type, each of the pocket wells including k*8n memory cells (n and k being positive integers, k being the number of rows and 8n being the number of columns of memory cells arranged in rows and columns); and
wherein the first gate electrode extends in a row direction to form a wordline, the second gate electrode spacer and the third gate electrode spacer extend in a row direction to form a first select line and a second select line respectively, the second impurity diffusion region extends in a row direction to form a common source line, and a bitline is electrically connected to the first impurity diffusion regions of a column direction.

12. The nonvolatile memory device as recited in claim 11, wherein a program operation for the memory cells is conducted using F-N tunneling.

13. The nonvolatile memory device as recited in claim 12, wherein the program operation for the memory cells is conducted by applying a program voltage to a selected wordline of the selected memory cell; applying a ground voltage to a bitline connected to the selected memory cell; applying an operation voltage to a selected first select line of the selected memory cell; and applying a ground voltage to a second select line of the selected memory cell, a common source line connected to the selected memory cell and a selected pocket well including the selected memory cell.

14. The nonvolatile memory device as recited in claim 13, wherein unselected wordlines are floated;
an operation voltage is applied to unselected wordlines; and
a ground voltage is applied to an unselected first select line, unselected second select lines, unselected common source lines, and unselected pocket wells.

15. The nonvolatile memory device as recited in claim 10, wherein an erase operation for selected memory cells in a selected pocket well of the first conductivity type is conducted by floating bitlines, common source lines, first select lines, and second select lines; applying a ground voltage to at least one of selected wordlines connected to the selected memory cell and floating unselected wordlines; applying an erase voltage to the selected pocket well; and applying a ground voltage to unselected pocket.

16. The nonvolatile memory device as recited in claim 10, wherein a read operation for a selected one of the memory cells is conducted by applying a ground voltage to a selected common source line connected to the selected memory cell and a selected pocket well; applying an operation voltage to a selected first select line of the selected memory cell; applying an operation voltage to a second select line of the selected memory cell; applying a first read voltage to a selected bitline connected to the selected memory cell; and applying a second read voltage to a selected wordline of the selected memory cell.

17. The nonvolatile memory device as recited in claim 16, wherein a ground voltage is applied to unselected common source lines and unselected pocket wells;
a ground voltage is applied to unselected first select lines;
an operation voltage is applied to unselected second select lines;
a ground voltage is applied to unselected bitlines; and
a blocking voltage is applied to unselected wordlines.

18. The nonvolatile memory device as recited in claim 11, wherein adjacent memory cells in a column direction share a first impurity diffusion region therebetween as a common drain region.

19. A nonvolatile memory device comprising:
memory cells arranged in a matrix of rows and columns;
source regions and drain regions self-aligned at a substrate outside of the memory cells, wherein adjacent source regions disposed in a row direction are connected to form a common source line; and
a bitline electrically connected to drain regions of a column direction,
wherein each of the memory cells includes a stacked gate structure and first and second select gates self-aligned on opposite sidewalls of the stacked gate structure, the stacked gate structure including a floating gate, a second insulation layer, and a control gate which are stacked on the semiconductor substrate with a first insulation layer interposed therebetween, and
wherein the control gate extends in a row direction to form a wordline, and the first and second select gates extend in a row direction to form first and second select lines, respectively.

20. The nonvolatile memory device as recited in claim 19, wherein different bias voltages are independently applied to the first and second select lines.

21. The nonvolatile memory device as recited in claim 19, wherein the semiconductor substrate includes a plurality of P-type pocket wells formed in an N-type well,
each of the P-type pocket wells including 2^{k-1}*8n memory cells (n and k being positive integers, 2^{k-1} being the number of memory cells arranged in a column direction, 8n being the number of memory cells arranged in a row direction) and first and second impurity diffusion regions disposed at opposite sides of the respective memory cells.

22. The nonvolatile memory device as recited in claim 21, wherein a program operation for the memory cells is conducted using F-N tunneling.

23. The nonvolatile memory device as recited in claim 22, wherein the program operation for a selected memory cells is conducted by applying a program voltage to a selected wordline of the selected memory cell; floating unselected wordlines; applying a ground voltage to a selected bitline connected to the selected memory cell and applying an operation voltage to unselected bitlines; applying an operation voltage to a selected first select line of the selected memory cell and applying a ground voltage to unselected first select lines; and applying a ground voltage to the second select lines, the common source lines, and the P-type pocket wells.

24. The nonvolatile memory device as recited in claim 22, wherein an erase operation for the selected memory cells in the selected P-type pocket wells is conducted by floating bitlines, common source lines, first select lines, and second select lines; applying a ground voltage to at least one selected wordline connected to the selected memory cells and floating unselected wordlines; and applying an erase voltage to the selected pocket well and applying a ground voltage to unselected pocket wells.

25. The nonvolatile memory device as recited in claim 22, wherein a read operation for a selected memory cell is conducted by applying a ground voltage to common source lines and the P-type pocket well; applying an operation voltage to a selected first select line of the selected memory cell and applying a ground voltage to unselected first select lines; applying an operation voltage to second select lines, applying a first read voltage to a selected bitline connected to the selected memory cell and applying a ground voltage to bitlines; and applying a second read voltage to a selected wordline of the selected memory cell and applying a blocking voltage to unselected wordlines.

26. A nonvolatile memory device comprising:
a semiconductor substrate including an N-type well and a P-type pocket well formed in the N-type well;
a stacked gate structure formed on the P-type pocket well with a first insulation layer interposed therebetween, the stacked gate structure including a floating gate, a second insulation layer, and a control gate;
a third insulation layer formed on the semiconductor substrate and the stacked gate structure;
a first select gate and a second select gate self-aligned on opposite sidewalls of the stacked gate structure with the third insulation layer interposed therebetween; and
an N-type drain region and an N-type source region self-aligned at P-type pocket wells disposed at opposite sides of the first and second select gates, respectively.

27. The nonvolatile memory device as recited in claim 26, wherein different bias voltages are independently applied to the first and second select gates.

28. The nonvolatile memory device as recited in claim 26, wherein a program operation for the memory cell is conducted by applying a program voltage to the control gate; applying an operation voltage to the first select gate;
and applying a ground voltage to the drain region, the second select gate, the source region, and the P-type pocket well.

29. The nonvolatile memory device as recited in claim 26, wherein sensing whether there are charges stored in the floating gate is done by applying a ground voltage to the source region and the P-type pocket well; applying a first read voltage to the drain region; applying a second read voltage to the control gate; and applying an operation voltage to the first and second select gates.

30. A nonvolatile memory device comprising:
a plurality of floating gate electrodes arranged at a semiconductor substrate in a matrix of rows and columns;
a plurality of wordlines each crossing over a plurality of the floating gate electrodes disposed in a row direction;
a first select line and a second select line in a row direction self-aligned on opposite sidewalls of the respective wordlines and floating gate electrodes;
drain regions formed in a semiconductor substrate outside the first select lines;
a plurality of bitlines connected to corresponding drain regions of a column direction;
source regions formed in a semiconductor substrate outside the second select lines, wherein source regions of a row direction are connected to form a common source line; and
the semiconductor substrate includes a plurality of pocket wells each including k*8n floating gate electrodes (n and k being positive integers, k being the number of rows in arrangement of floating gate electrodes arranged in a matrix of rows and columns, and 8n being the number of columns in arrangement thereof).

31. The nonvolatile memory device as recited in claim 30, wherein adjacent memory cells disposed in a column direction share a drain region therebetween.

32. The nonvolatile memory device as recited in claim 30, wherein at program, erase, and read operations for the memory cell, different bias voltages are independently applied to the first and second select lines.

33. The nonvolatile memory device as recited in claim 30, wherein a program operation for the memory cell is conducted using F-N tunneling.
